(19) United States
(12) Patent Application Publication
(10) Pub. No.: US 2021/0219459 A1
(43) Pub. Date: Jul. 15, 2021

(54) TWO-PHASE MANIFOLD COLD PLATE FOR LIQUID COOLING

(71) Applicant: Intel Corporation, Santa Clara, CA (US)

(72) Inventors: Jin YANG, Hillsboro, OR (US); David SHIA, Portland, OR (US); Mohanraj PRABHUGOUD, Hillsboro, OR (US)

(21) Appl. No.: 17/195,354

(22) Filed: Mar. 8, 2021

(51) Int. Cl. H05K 7/20; H01L 23/427

(52) U.S. Cl. CPC H05K 7/20509; H05K 7/20309; H01L 23/427; H05K 7/20809; H05K 7/20327

(57) ABSTRACT

An apparatus is described. The apparatus includes a cold plate having columns of fluidic channels. The fluidic channels have a length such that coolant that flows through the fluidic channels will be composed less of vapor than of liquid and a mix of liquid and vapor over a rated power range of one or more semiconductor chips that are cooled by the cold plate.

### BACKGROUND

The total power consumption of computing and/or networking systems continues to scale upward with the increasing performance of these systems. A significant component of a system's total power consumption is the power consumption of any/all of its high performance semiconductor chips(s) and/or electro-optic devices. Because the heat generated by an electronic device increases with its power consumption, systems designers are increasingly presented with thermal related hurdles and designing their systems to overcome them.

### FIGURES

A better understanding of the present invention can be obtained from the following detailed description in conjunction with the following drawings, in which:

FIG. 1 shows a data center with liquid cooled electronic systems;

FIG. 2 shows cold plates mounted on packages;

FIGS. 3a and 3b show a prior art cold plate;

FIG. 4 shows an improved cold plate;

FIGS. 5a, 5b and 5c show detailed views of an improved cold plate;

FIG. 6 shows another improved cold plate;

FIG. 7 shows a system;

FIG. 8 shows a data center;

FIG. 9 shows a rack.

### DESCRIPTION

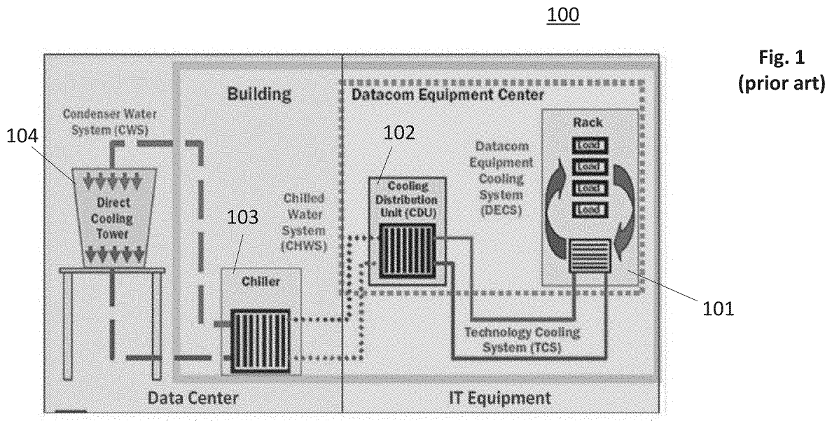

FIG. 1 shows a high-level depiction of a high performance computing environment 100 such as a centralized data center or cloud service nerve center using standard liquid cooling. As observed in FIG. 1, multiple racks 101 each containing shelves of computing equipment (generally called chassis) are located in a confined area. Generally, information systems (IS) managers desire to pack large amounts of computing performance into small areas. Likewise, semiconductor chip manufacturers and computing equipment manufacturers attempt to densely integrate high performance functionality into their respective products.

As the performance of semiconductor chips (and the computing/networking systems that the chips are integrated into) continues to increase, however, so does the associated power consumption. Unfortunately, the performance of many semiconductor chips and computing/networking system products has crossed a threshold at which traditional air-cooling is unable to keep the chips/equipment sufficiently cool.

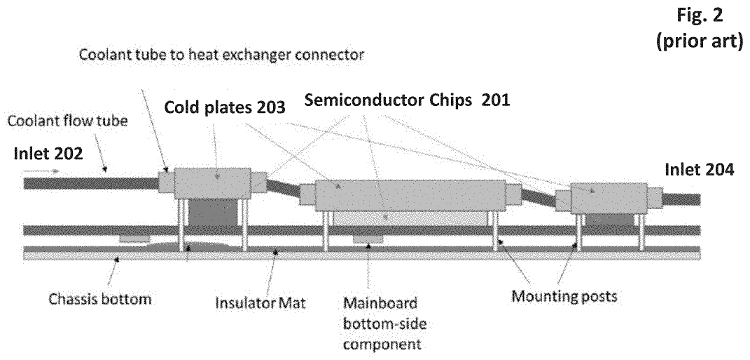

As such, liquid cooling solutions are steadily being integrated into today's computing/networking systems. Here, as observed in FIG. 2, a computing system or networking system (“system”), such as a blade server, a disaggregated computing system CPU unit, a switching hub, etc., includes a number of semiconductor chips 201. The system also includes an inlet 202 to receive cooled fluid. Cold plates 203 are mechanically coupled to various semiconductor chips 201 within the system and the cooled fluid is routed, e.g., by way of one or more manifolds and conduit tubing, through the cold plates 203.

As the semiconductor chips 201 operate they transfer heat to their respective cold plates 203, which, in turn, transfers the heat to the running fluid (there is no direct contact of the coolant to the electronic devices). The warmed fluid is then collected through one or more manifolds and tubing and routed to a warmed fluid outlet port 204. Note that although FIG. 2 depicts cold plates attached to the semiconductor chips 201, other liquid cooling solutions attach heat exchangers to the semiconductor chips 201. Both cold plates and heat exchangers have fluid input/output junctions as depicted.

The simple running of cooled liquid into a cold plate and warmed liquid out of a cold plate is referred to as “single-phase” cooling. That is, the coolant (with a relatively high boiling point, e.g., above 100° C.) enters the cold plate as a liquid, remains a liquid within the cold plate, and then ultimately exits the cold plate as a liquid. Because the coolant remains a constant/single phase (a liquid) throughout its flow through the cold plate, it is regarded as a “single phase” technique.

Improved cooling can be achieved with “two-phase” cooling. In the case of two-phase cooling, the coolant enters the cold plate as a liquid and then is deliberately evaporated into a vapor. Here, the activity of vaporizing a liquid provides better cooling efficiency as compared to a single-phase approach. After vaporizing the coolant, the coolant exits the cold plate as a vapor.

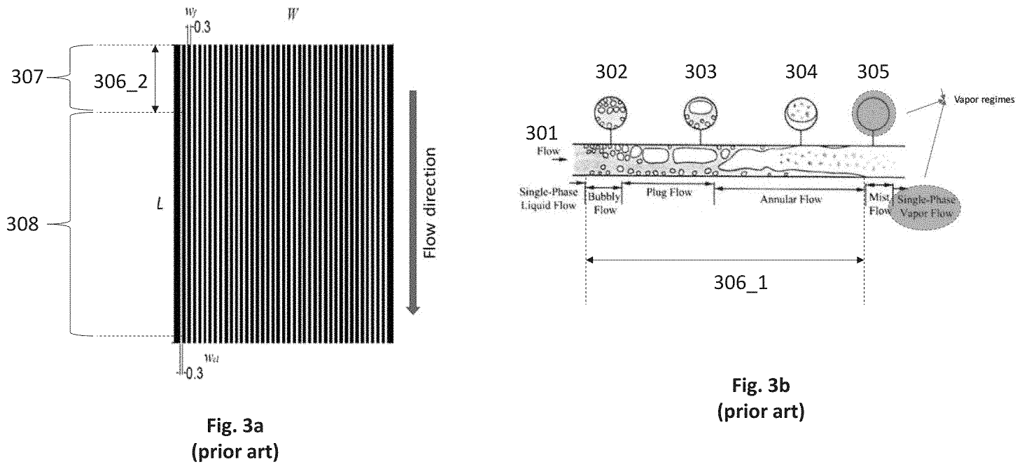

FIG. 3a shows a top down view of the fluidic channels of a prior art two-phase cold plate. As can be observed in FIG. 3a, the cold plate is composed of long, thin fluidic channels. The cold plate is formed, e.g., from a copper base plate having fins that protrude upward from the base plate's surface. A top cover, which is only a simple solid copper plate without internal structure is placed over the fins to form enclosed fluidic channels between fins. The copper base plate is placed on the semiconductor chip package and receives heat from the semiconductor chip package. Coolant runs through the channels and receives heat from the chip via the chip package and copper base plate. The heat ultimately vaporizes the liquid and vapor is vented from the cold plate through one-direction long, thin fin banks.

FIG. 3b depicts the evaporation process within a fluidic channel in more detail. As observed in FIG. 3b, coolant first enters a fluidic channel in a liquid phase 301 and begins to receive heat. The increased temperature of the liquid, in turn, nucleates bubbles 302 within the liquid. The liquid continues to receive heat as it flows through the channel which causes larger bubbles 303 (“plugs”) to be formed further along the channel.

As the liquid continues to receive more heat as it flows down the channel, the plugs expand until there is only an annulus of liquid 304 flowing along the outer edges of the channel (the center region of the channel is vapor). Finally, with even more heat being transferred to the liquid as it continues to flow down the channel, the liquid fully evaporates and only vapor 305 remains throughout the remainder of the channel.

Unfortunately, particularly when the underlying semiconductor chip is dissipating large amounts of heat, the liquid can reach full evaporation 305 shortly after it enters the fluidic channels. That is, the referring to FIG. 3b, the distance 306_1 between a fluidic channel's input port and where the fluid becomes fully vaporized is substantially shorter than the length of the fluidic channel.

Here, for example, referring to FIG. 3a, if the coolant is fully vaporized after it has traveled only a distance 306_2 along each of the fluidic channels, liquid or a mix of liquid and vapor will exist only within region 307 of the channels whereas only vapor will exist within region 308 of the channels.

A large pocket of vapor within the cold plate's fluidic channels can reduce the overall heat transfer efficiency of the cold plate. Specifically, direct heat transfer to the vapor region 308 is less efficient than to the liquid/mix region 307. As such, even though a two-phase cooling process is present, heat generated from a large region of the chip package (approximately the region beneath region 308) will be inefficiently transferred to vapor.

Additionally, the presence of vapor within a large region 308 of the fluidic channels lowers the pressure within the channels which, in turn, can cause the size of the vapor region 308 to undesirably expand and contract (oscillate) within the cold plate.

Regardless, reducing the size of the vapor region 308 within the fluidic channels will enhance overall heat transfer efficiency. Said another way, the advantage of evaporation as a cooling dynamic will be better spread out over the run length of the fluidic channels rather than being confined into just a small initial flow region 307 of the fluidic channels.

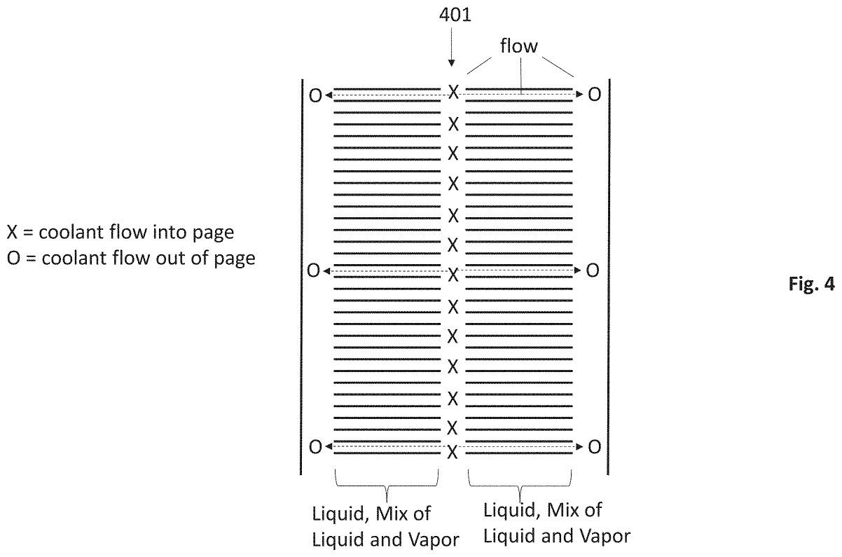

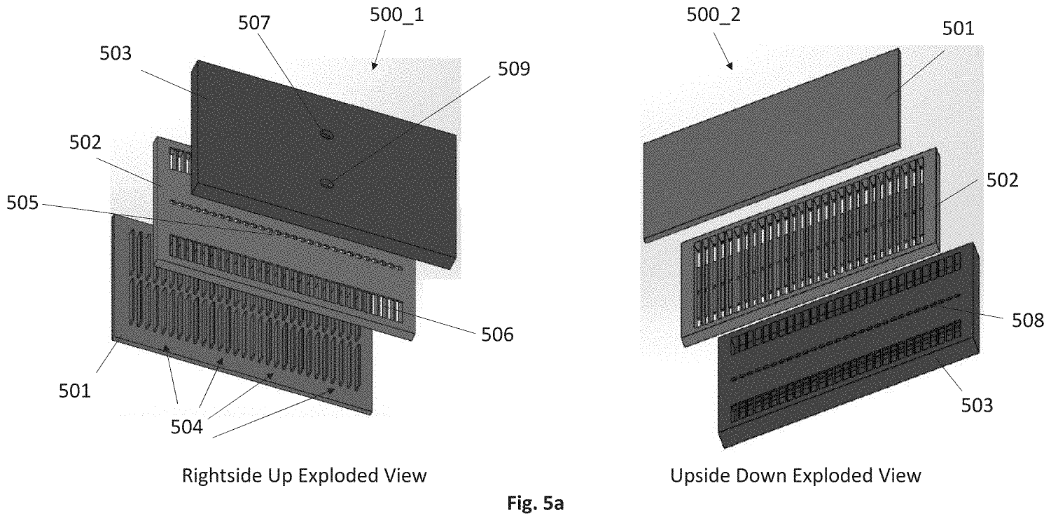

FIG. 4 shows a top down view of the fluidic channels of an embodiment of an improved cold plate design. Comparing the prior art design of FIG. 3a against the improved design of FIG. 4, note that the improved design includes more channels having shorter length as compared to the prior art design. Here, in various embodiments, the length of the channels in the improved design are comparable to the channel distance where the coolant will be completely vaporized.

As such, the channels will contain primarily liquid or a mix of liquid and vapor (any “vapor only” region exists toward the end of the channels). By designing the run-length of the channels to terminate shortly after the liquid has completely vaporized, vaporization activity exists through most of the channel which, in turn, realizes two phase cooling efficiencies over most (if not all) of the channel's run length.

More specifically, in the case of the prior art cold plate of FIG. 3a, when the semiconductor chip operates at its highest rated power, only vapor is present within at least half the run length of the fluidic channels. By contrast, in the improved approach of FIG. 4, when the semiconductor chip operates at its highest rated power, more than half the run length of the fluidic channels is liquid or a mix of vapor and liquid. As such, only vapor is present is less than half the run length of the fluidic channels (e.g., only the last 33%, 25%, 10%, etc. of the run length of the fluidic channels contains only vapor) when the semiconductor chip is operating at maximum power. Because the extent of a vapor only region decreases as the semiconductor chip decreases its power consumption, the condition that more than half the run length of the fluidic channels is liquid or a mix of vapor and liquid is met over the entire rated power range of the semiconductor chip.

As observed in FIG. 4, the improved cold plate is designed to flow input coolant liquid downward into a mid-section 401 of the cold plate. The coolant then flows laterally outward along the channels (FIG. 4 illustrates only a few coolant flows for illustrative ease). With the coolant being converted to vapor near the ends of the channels, the vapor is collected at the channel ends and rises upward from the base of the cold plate.

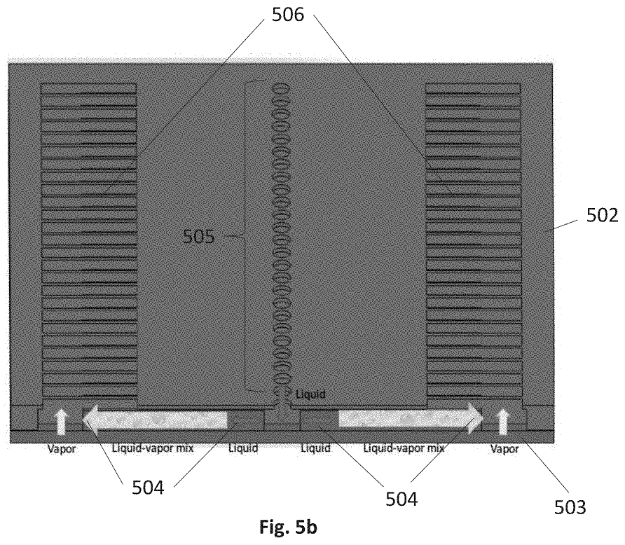

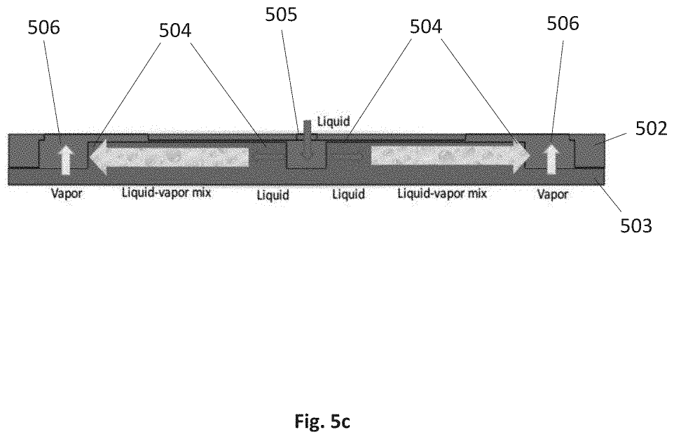

FIGS. 5a, 5b and 5c show a more detailed view of the improved design. FIG. 5a shows a right side up exploded view 500_1 and an upside down exploded view 500_2 (the upside down exploded view 500_2 shows the understructure of the features of the right side up view 500_1), FIG. 5b shows an angled view and FIG. 5c shows a cross sectional side view. As observed in FIGS. 5a, 5b and 5c, the cold plate is composed of a base layer 501, a mid layer 502 and a manifold 503.

In the particular embodiment, the base layer 501 is composed of a thermally conductive material (e.g., a metal such as copper). The base layer 501 is positioned in contact with the chip package and receives heat from the semiconductor chip through the package.

The base layer 501 is also formed to have fins 504 that stand upright from the upper surface of the base layer 501. The space between the fins corresponds to the cold plate's fluidic channels. The mid layer 502 is placed on the fins 504 and forms the upper surface of the fluidic channels. The mid layer 502 also has openings that form the entrance ports to the channels 505 and the exit vents from the channels 506. A manifold 503 is then placed over the mid layer 502.

Input coolant enters the manifold 503 at an input 507 and falls through holes 508 that are formed in the bottom of manifold 503 along a mid section of the manifold. The input ports 505 to the fluidic channels in the mid layer 502 are also formed beneath the holes 508 in the manifold. As such, the input fluid that falls through the holes 508 in the manifold 503 then enters the entrance ports 505 to the channels. Inside the manifold 503, in various embodiments, there is one or more liquid distribution channel(s) designed to distribute the liquid more evenly to the inlet ports.

The fluid then flows laterally through the fluidic channels toward the edges of the cold plate. As discussed at length above, vaporization is realized shortly before the channels terminate. The vapor exits the channels by rising through the exit vents 506 formed in the mid layer 502 and into the manifold 503 and out the cold plate output 509. Here, the manifold 503 may have separated chambers/compartments/channels (not shown) for entrance fluid and exit vapor so the two are not mixed.

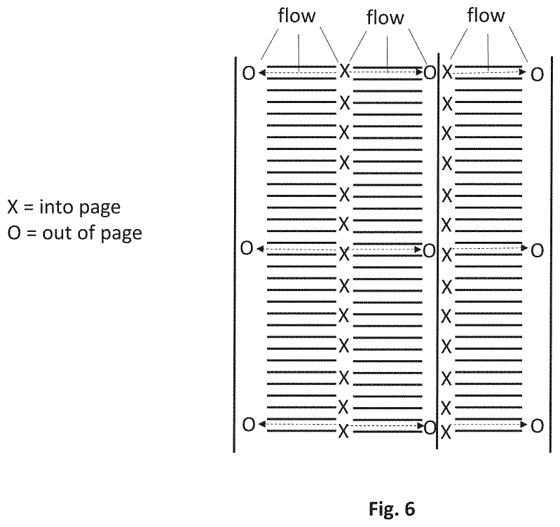

FIG. 6 shows another embodiment that includes three columns of channels rather than two columns of channels as depicted in the embodiment of FIGS. 5a, 5b and 5c. In the embodiment of FIG. 6, the manifold and mid layer are formed to cause input fluid to fall through holes aligned with the channel inputs, and, vapor to exit the channels through vents aligned with the channel outputs.

Here, the run-length along a channel at which the input coolant will be completely vaporized depends on various factors such as the worst case heat dissipation from the underlying chip, the type of coolant used, the applicable pump pressure, etc. For implementations having a shorter run-length to complete vaporization, more columns of shorter channels (like the approach of FIG. 6) can be implemented. Thus, even further embodiments (not depicted) can include four, five, six, etc. columns of channels where the channel length decreases with each next column of channels.

Although the above discussion has emphasized placement of the aforementioned cold plate on a single chip package, in other embodiments the cold plate can be placed on a multi-chip package (which is a package that contains multiple semiconductor chips) or electro-optical component package.

Moreover, although the discussion above has emphasized the mid-layer 502 and manifold components 503 as being separate components, in alternate embodiments these two components can be integrated into a single component (which, e.g., can be referred to as a manifold).

Examples of chip(s) that can be within any such package include a processor (CPU), (system-on-chip, accelerator chip (e.g., neural network processor), graphics processing unit (GPU), general purpose graphics processing unit (GPGPU), field programmable gate array (FPGA), application specific integrated circuit (ASIC)), high bandwidth memory (HBM) or other built in memory, an “X” processing unit (“XPU”) where “X” can be any processor other than a general purpose processor (e.g., etc. G for graphics, D for data, I for infrastructure, etc.).

Electrical I/Os can emanate from a package with a cold plate as described above and/or an electrical system having a package with a cold plate as described above. Examples include, e.g., data and/or clocking signals associated with any of Infinity Fabric (e.g., as associated and/or implemented with AMD products) or derivatives thereof, specifications developed by the Cache Coherent Interconnect for Accelerators (CCIX) consortium or derivatives thereof, specifications developed by the GEN-Z consortium or derivatives thereof, specifications developed by the Coherent Accelerator Processor Interface (CAPI) or derivatives thereof, specifications developed by the Compute Express Link (CXL) consortium or derivatives thereof, specifications developed by the Hyper Transport consortium or derivative thereof, Ethernet, Infiniband, NVMe-oF, PCIe, etc.

Any electrical system having a cold plate disposed on a package as described above can be a rack mountable system having dimensions that are compatible with an industry standard rack (such as racks having 19″ or 23″ widthwise openings and having mounting holes for chassis having heights of specific height units (e.g., 1U, 2U, 3U where U=1.75″). One example is the IEC 60297 Mechanical structures for electronic equipment—Dimensions of mechanical structures of the 482.6 mm (19 in) series. Generally, however, a chassis of any dimension is possible.

The chassis can contain the primary components of an entire computer system (e.g., CPU, main memory controller, main memory, peripheral controller and mass non-volatile storage), or, may contain the functionality of just some subset of an entire computer system (e.g., a chassis that contains primarily CPU processor power, a chassis that contains primarily main memory control and main memory, a chassis that contains primarily a storage controller and storage). The later can be particularly useful for dis-aggregated computing systems.

In the case of a dis-aggregated computer system, unlike a traditional computer in which the core components of a computing system (e.g., CPU processors, memory, storage, accelerators, etc.) are all housed within a common chassis and connected to a common motherboard, such components are instead integrated on separate pluggable cards or other pluggable components (e.g., a CPU card, a system memory card, a storage card, an accelerator card, etc.) that plug-into a larger exposed backplane or network instead of a same, confined motherboard. As such, for instance, CPU computer power can be added by adding CPU cards to the backplane or network, system memory can be added by adding memory cards to the backplane or network, etc. Such systems can exhibit even more high-speed card to card connections that traditional computers. One or more dis-aggregated computers and/or traditional computers/servers can be identified as a Point of Delivery (PoD) for computing system function in, e.g., the larger configuration of an information technology (IT) implementation such as a data center.

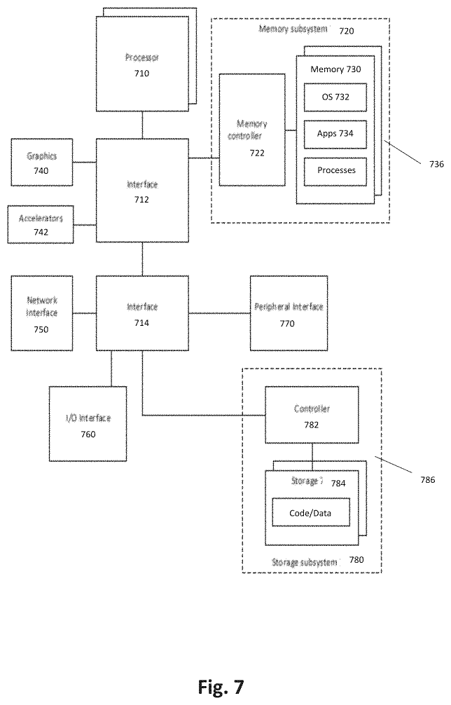

FIG. 7 depicts an example system. The system can use embodiments described herein to determine a reference voltage to apply to a rank of memory devices and a timing delay of a chip select (CS) signal sent to the rank of memory devices. System 700 includes processor 710, which provides processing, operation management, and execution of instructions for system 700. Processor 710 can include any type of microprocessor, central processing unit (CPU), graphics processing unit (GPU), processing core, or other processing hardware to provide processing for system 700, or a combination of processors. Processor 710 controls the overall operation of system 700, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, system 700 includes interface 712 coupled to processor 710, which can represent a higher speed interface or a high throughput interface for system components that needs higher bandwidth connections, such as memory subsystem 720 or graphics interface components 740, or accelerators 742. Interface 712 represents an interface circuit, which can be a standalone component or integrated onto a processor die. Where present, graphics interface 740 interfaces to graphics components for providing a visual display to a user of system 700. In one example, graphics interface 740 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 740 generates a display based on data stored in memory 730 or based on operations executed by processor 710 or both. In one example, graphics interface 740 generates a display based on data stored in memory 730 or based on operations executed by processor 710 or both.

Accelerators 742 can be a fixed function offload engine that can be accessed or used by a processor 710. For example, an accelerator among accelerators 742 can provide compression (DC) capability, cryptography services such as public key encryption (PKE), cipher, hash/authentication capabilities, decryption, or other capabilities or services. In some embodiments, in addition or alternatively, an accelerator among accelerators 742 provides field select controller capabilities as described herein. In some cases, accelerators 742 can be integrated into a CPU socket (e.g., a connector to a motherboard or circuit board that includes a CPU and provides an electrical interface with the CPU). For example, accelerators 742 can include a single or multi-core processor, graphics processing unit, logical execution unit single or multi-level cache, functional units usable to independently execute programs or threads, application specific integrated circuits (ASICs), neural network processors (NNPs), “X” processing units (XPUs), programmable control logic, and programmable processing elements such as field programmable gate arrays (FPGAs). Accelerators 742 can provide multiple neural networks, processor cores, or graphics processing units can be made available for use by artificial intelligence (AI) or machine learning (ML) models. For example, the AI model can use or include any or a combination of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 720 represents the main memory of system 700 and provides storage for code to be executed by processor 710, or data values to be used in executing a routine. Memory subsystem 720 can include one or more memory devices 730 such as read-only memory (ROM), flash memory, volatile memory, or a combination of such devices. Memory 730 stores and hosts, among other things, operating system (OS) 732 to provide a software platform for execution of instructions in system 700. Additionally, applications 734 can execute on the software platform of OS 732 from memory 730. Applications 734 represent programs that have their own operational logic to perform execution of one or more functions. Processes 736 represent agents or routines that provide auxiliary functions to OS 732 or one or more applications 734 or a combination. OS 732, applications 734, and processes 736 provide software logic to provide functions for system 700. In one example, memory subsystem 720 includes memory controller 722, which is a memory controller to generate and issue commands to memory 730. It will be understood that memory controller 722 could be a physical part of processor 710 or a physical part of interface 712. For example, memory controller 722 can be an integrated memory controller, integrated onto a circuit with processor 710. In some examples, a system on chip (SOC or SoC) combines into one SoC package one or more of: processors, graphics, memory, memory controller, and Input/Output (I/O) control logic.

A volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/Output version 2, JESD229-2 originally published by JEDEC in August 2014, HBM (High Bandwidth Memory, JESD325, originally published by JEDEC in October 2013, LPDDR5 (currently in discussion by JEDEC), HBM2 (HBM version 2), currently in discussion by JEDEC, or others or combinations of memory technologies, and technologies based on derivatives or extensions of such specifications. The JEDEC standards are available at www.jedec.org.

While not specifically illustrated, it will be understood that system 700 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect express (PCIe) bus, a HyperTransport or industry standard architecture (ISA) bus, a small computer system interface (SCSI) bus, Remote Direct Memory Access (RDMA), Internet Small Computer Systems Interface (iSCSI), NVM express (NVMe), Coherent Accelerator Interface (CXL), Coherent Accelerator Processor Interface (CAPI), a universal serial bus (USB), or an Institute of Electrical and Electronics Engineers (IEEE) standard 1394 bus.

In one example, system 700 includes interface 714, which can be coupled to interface 712. In one example, interface 714 represents an interface circuit, which can include standalone components and integrated circuitry. In one example, multiple user interface components or peripheral components, or both, couple to interface 714. Network interface 750 provides system 700 the ability to communicate with remote devices (e.g., servers or other computing devices) over one or more networks. Network interface 750 can include an Ethernet adapter, wireless interconnection components, cellular network interconnection components, USB (universal serial bus), or other wired or wireless standards-based or proprietary interfaces. Network interface 750 can transmit data to a remote device, which can include sending data stored in memory. Network interface 750 can receive data from a remote device, which can include storing received data into memory. Various embodiments can be used in connection with network interface 750, processor 710, and memory subsystem 720.

In one example, system 700 includes one or more input/output (I/O) interface(s) 760. I/O interface 760 can include one or more interface components through which a user interacts with system 700 (e.g., audio, alphanumeric, tactile/touch, or other interfacing). Peripheral interface 770 can include any hardware interface not specifically mentioned above. Peripherals refer generally to devices that connect dependently to system 700. A dependent connection is one where system 700 provides the software platform or hardware platform or both on which operation executes, and with which a user interacts.

In one example, system 700 includes storage subsystem 780 to store data in a nonvolatile manner. In one example, in certain system implementations, at least certain components of storage 780 can overlap with components of memory subsystem 720. Storage subsystem 780 includes storage device(s) 784, which can be or include any conventional medium for storing large amounts of data in a nonvolatile manner, such as one or more magnetic, solid state, or optical based disks, or a combination. Storage 784 holds code or instructions and data 786 in a persistent state (e.g., the value is retained despite interruption of power to system 700). Storage 784 can be generically considered to be a “memory,” although memory 730 is typically the executing or operating memory to provide instructions to processor 710. Whereas storage 784 is nonvolatile, memory 730 can include volatile memory (e.g., the value or state of the data is indeterminate if power is interrupted to system 700). In one example, storage subsystem 780 includes controller 782 to interface with storage 784. In one example controller 782 is a physical part of interface 714 or processor 710 or can include circuits or logic in both processor 710 and interface 714.

A non-volatile memory (NVM) device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

A power source (not depicted) provides power to the components of system 700. More specifically, power source typically interfaces to one or multiple power supplies in system 900 to provide power to the components of system 700. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 700 can be implemented as a disaggregated computing system. For example, the system 700 can be implemented with interconnected compute sleds of processors, memories, storages, network interfaces, and other components. High speed interconnects can be used such as PCIe, Ethernet, or optical interconnects (or a combination thereof). For example, the sleds can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

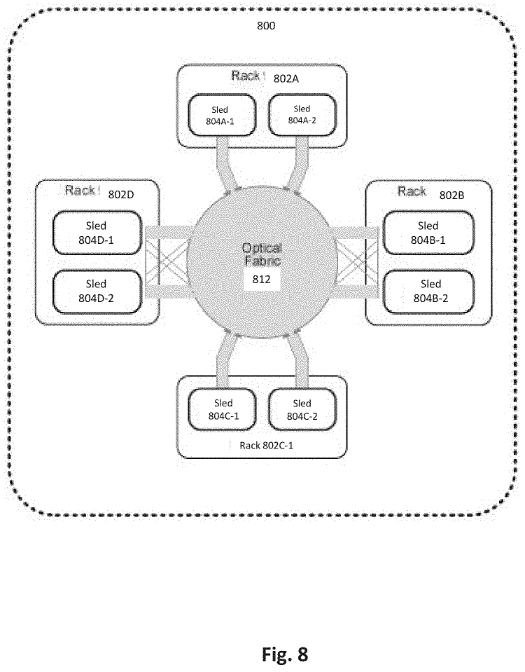

FIG. 8 depicts an example of a data center. Various embodiments can be used in or with the data center of FIG. 8. As shown in FIG. 8, data center 800 may include an optical fabric 812. Optical fabric 812 may generally include a combination of optical signaling media (such as optical cabling) and optical switching infrastructure via which any particular sled in data center 800 can send signals to (and receive signals from) the other sleds in data center 800. However, optical, wireless, and/or electrical signals can be transmitted using fabric 812. The signaling connectivity that optical fabric 812 provides to any given sled may include connectivity both to other sleds in a same rack and sleds in other racks. Data center 800 includes four racks 802A to 802D and racks 802A to 802D house respective pairs of sleds 804A-1 and 804A-2, 804B-1 and 804B-2, 804C-1 and 804C-2, and 804D-1 and 804D-2. Thus, in this example, data center 800 includes a total of eight sleds. Optical fabric 812 can provide sled signaling connectivity with one or more of the seven other sleds. For example, via optical fabric 812, sled 804A-1 in rack 802A may possess signaling connectivity with sled 804A-2 in rack 802A, as well as the six other sleds 804B-1, 804B-2, 804C-1, 804C-2, 804D-1, and 804D-2 that are distributed among the other racks 802B, 802C, and 802D of data center 800. The embodiments are not limited to this example. For example, fabric 812 can provide optical and/or electrical signaling.

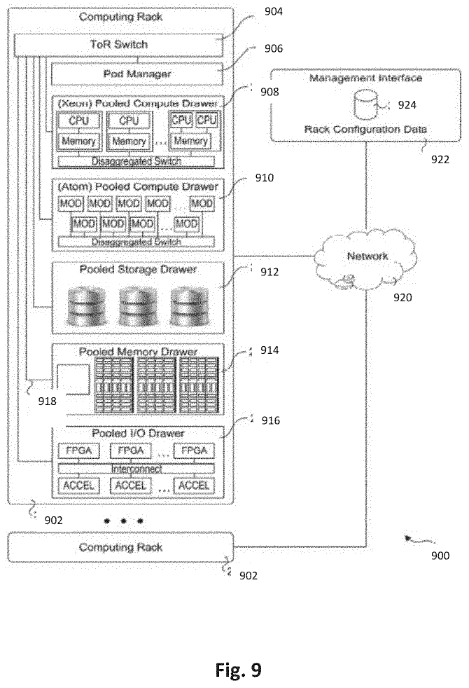

FIG. 9 depicts an environment 900 includes multiple computing racks 902, each including a Top of Rack (ToR) switch 904, a pod manager 906, and a plurality of pooled system drawers. Generally, the pooled system drawers may include pooled compute drawers and pooled storage drawers to, e.g., effect a disaggregated computing system. Optionally, the pooled system drawers may also include pooled memory drawers and pooled Input/Output (I/O) drawers. In the illustrated embodiment the pooled system drawers include an INTEL® XEON® pooled computer drawer 908, and INTEL® ATOM™ pooled compute drawer 210, a pooled storage drawer 212, a pooled memory drawer 214, and an pooled I/O drawer 916. Each of the pooled system drawers is connected to ToR switch 904 via a high-speed link 918, such as a 40 Gigabit/second (Gb/s) or 100 Gb/s Ethernet link or an 100+Gb/s Silicon Photonics (SiPh) optical link. In one embodiment high-speed link 918 comprises an 800 Gb/s SiPh optical link.

Again, the drawers can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Multiple of the computing racks 900 may be interconnected via their ToR switches 904 (e.g., to a pod-level switch or data center switch), as illustrated by connections to a network 920. In some embodiments, groups of computing racks 902 are managed as separate pods via pod manager(s) 906. In one embodiment, a single pod manager is used to manage all of the racks in the pod. Alternatively, distributed pod managers may be used for pod management operations.

RSD environment 900 further includes a management interface 922 that is used to manage various aspects of the RSD environment. This includes managing rack configuration, with corresponding parameters stored as rack configuration data 924.

Embodiments herein may be implemented in various types of computing, smart phones, tablets, personal computers, and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation. It is noted that hardware, firmware and/or software elements may be collectively or individually referred to herein as “module,” “logic,” “circuit,” or “circuitry.”

Some examples may be implemented using or as an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

One or more aspects of at least one example may be implemented by representative instructions stored on at least one machine-readable medium which represents various logic within the processor, which when read by a machine, computing device or system causes the machine, computing device or system to fabricate logic to perform the techniques described herein. Such representations, known as “IP cores” may be stored on a tangible, machine readable medium and supplied to various customers or manufacturing facilities to load into the fabrication machines that actually make the logic or processor

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences of steps may also be performed according to alternative embodiments. Furthermore, additional steps may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

Embodiments have been described above including an apparatus having a cold plate. The cold plate has columns of fluidic channels. The fluidic channels have a length designed to ensure that coolant that flows through the fluidic channels will be composed less of vapor than of liquid and a mix of liquid and vapor.

In further embodiments the columns of fluidic channels comprise a first column of fluidic channels and a second column of fluidic channels, wherein, coolant flows in a first direction in the first column of fluidic channels that is opposite a second direction that coolant flows in the second column of fluidic channels.

In other further embodiments the cold plate has a base having fins that emanate from a first surface of the base that is opposite a second surface of the base that is to be placed in contact with a package containing a device that generates heat. The fins form sides of the fluidic channels. In further additional embodiments the cold plate has a structure on the fins having holes that form input ports to the fluidic channels and vents that form exit ports from the fluidic channels. In other further additional embodiments the cold plate comprises copper.

In still other further embodiments the cold plate has a manifold that provides input coolant to the fluidic channels and receives output vapor from the fluidic channels.

In yet other further embodiments, the columns of fluidic channels comprises first, second and third columns of fluidic channels.

A data center has been described. The data center has racks of electronic systems. The racks of electronic systems are at least partially coupled by an optical link, wherein, at least one of the electronic systems has a package containing a device that generates heat and a cold plate on the package. The cold plate is as described just above.

A method has been described. The method includes receiving heat from a package having a device that generates the heat. The method also includes flowing coolant through multiple columns of fluidic channels. The flowing coolant receives the heat. The heat causes the flowing coolant to convert from a liquid to a vapor within the fluidic channels, such that less vapor exists in the fluidic channels than liquid and a mix of liquid and vapor.

In further embodiment, the coolant flows in a first direction through a first group of the fluidic channels that is opposite a second direction that the coolant flows in a second group of the fluidic channels.

In another further embodiment the coolant is directed to fall into the fluidic channels and vapor that rises out of the fluidic channels is collected.

In another further embodiment, the multiple columns of fluidic channels comprise more than two columns of fluidic channels.

1. An apparatus, comprising:
a cold plate comprising columns of fluidic channels, the fluidic channels having a length such that coolant that flows through the fluidic channels will be composed less of vapor than of liquid and a mix of liquid and vapor over a rated power range of one or more semiconductor chips that are cooled by the cold plate.

2. The apparatus of claim 1 wherein the columns of fluidic channels comprise a first column of fluidic channels and a second column of fluidic channels, wherein, coolant is to flow in a first direction in the first column of fluidic channels that is opposite a second direction that coolant is to flow in the second column of fluidic channels.

3. The apparatus of claim 1 wherein the cold plate comprises a base having fins that emanate from a first surface of the base that is opposite a second surface of the base that is to be placed in contact with a package containing a device that generates heat, the fins forming sides of the fluidic channels.

4. The apparatus of claim 2 wherein the cold plate comprises a structure on the fins having holes that form input ports to the fluidic channels and vents that form exit ports from the fluidic channels.

5. The apparatus of claim 2 wherein the cold plate comprises copper.

6. The apparatus of claim 1 wherein the cold plate comprises a manifold that provides input coolant to the fluidic channels and receives output vapor from the fluidic channels.

7. The apparatus of claim 1 wherein the columns of fluidic channels comprises first, second and third columns of fluidic channels.

8. The apparatus of claim 1 wherein the one or more semiconductor chips comprise a processor.

9. A data center, comprising
racks of electronic systems, the racks of electronic systems at least partially coupled by an optical link, wherein, at least one of the electronic systems comprises:
a) a package containing a device that generates heat;
b) a cold plate on the package, the cold plate comprising a manifold to distribute coolant inside the cold plate to columns of fluidic channels, the fluidic channels having a length such that the coolant that flows through the fluidic channels will be composed less of vapor than of liquid and a mix of liquid and vapor over a rated power range of one or more semiconductor chips that are cooled by the cold plate.

10. The data center of claim 9 wherein the columns of fluidic channels a first column of fluidic channels and a second column of fluidic channels, wherein, coolant flows in a first direction in the first column of fluidic channels that is opposite a second direction that coolant flows in the second column of fluidic channels.

11. The data center of claim 9 wherein the cold plate comprises a base having fins that emanate from a first surface of the base that is opposite a second surface of the base that is to be placed in contact with a package containing a device that generates heat, the fins forming sides of the fluidic channels.

12. The data center of claim 10 wherein the cold plate comprises structure on the fins having holes that form input ports to the fluidic channels and vents that form exit ports from the fluidic channels.

13. The data center of claim 10 wherein the cold plate comprises copper.

14. The data center of claim 9 wherein the cold plate comprises a manifold that provides input coolant to the fluidic channels and receives output vapor from the fluidic channels.

15. The data center of claim 9 wherein the columns of fluidic channels comprise first, second and third columns of fluidic channels.

16. A method, comprising:
receiving heat from a package having a device that generates the heat at a maximum rated power; and,
flowing coolant through multiple columns of fluidic channels, the flowing coolant receiving the heat, the heat causing the flowing coolant to convert from a liquid to a vapor within the fluidic channels, such that less vapor exists in the fluidic channels than liquid and a mix of liquid and vapor.

17. The method of claim 16 wherein the coolant flows in a first direction through a first group of the fluidic channels that is opposite a second direction that the coolant flows in a second group of the fluidic channels.

18. The method of claim 16 further comprising directing the coolant to fall into the fluidic channels and collecting vapor that rises out of the fluidic channels.

19. The method of claim 16 wherein the multiple columns of fluidic channels comprise more than two columns of fluidic channels.
